(19) United States
(12) Patent Application Publication
(10) Pub. No.: US 2017/0369207 A1
(43) Pub. Date: Dec. 28, 2017

(54) DEVICE FOR CHECKING WHETHER A PACKAGE HAS BEEN OPENED OR NOT AND METHOD FOR PRODUCING SAID DEVICE

(71) Applicant: Robert Bosch GmbH, Stuttgart (DE)

(72) Inventors: Andreas Kugler, Alfdorf (DE); Berend Oberdorfer, Pfullingen (DE); Markus Hanisch, Markgroeningen (DE); Matthias Mahlich, Fellbach (DE); Sandra Woehr, Rutesheim (DE); Ulrich Wieduwilt, Schwaebisch Gmuend (DE); Markus Mueller, Waiblingen (DE)

(21) Appl. No.: 15/525,858

(22) PCT Filed: Sep. 10, 2015
(86) PCT No.: PCT/EP2015/070684

§ 371 Date: May 10, 2017

(30) Foreign Application Priority Data
Nov. 14, 2014 (DE) 10 2014 223 256.2

(51) Int. Cl. B65D 27/30; B65D 5/42; H05K 1/02; H05K 3/00

(52) U.S. Cl. CPC B65D 27/30; H05K 1/0275; B65D 5/42; B65D 2101/0069; H05K 3/00; B65D 2211/00

(57) ABSTRACT

The invention relates to a device for checking whether a package has been opened or not, comprising at least one package (10), at least one electronic unit (18), at least one battery (12) which supplies the electronic unit (18) with energy, at least one display (14) which can be controlled by the electronic unit (18), said electronic unit (18), the battery (12) and the display (14) being arranged on the package (10). At least two contact tracks (23, 24) and/or electrodes (26, 28) and/or at least one strain sensor (25) are provided as means for detecting whether the package (10) has been opened or not.

### BACKGROUND OF THE INVENTION

The invention is based on a device for sensing whether a package has been opened, and a method for producing the device. A device of the generic type is already disclosed by DE 603 04 601 T2. In said document, an electronic manipulation detection system comprises a corresponding electronics system which identifies opening, in particular of a folding box. Closure flaps are provided with electrically conductive adhesive for this purpose. Separation of the flaps interrupts an electrical circuit which comprises an electronics system which records the interruption, together with a time stamp, in a data memory of the electronics system.

### SUMMARY OF THE INVENTION

The object of the invention is to further simplify the device of the generic type.

In comparison, the device according to the invention for sensing whether a package has been opened has the advantage that the package can be manufactured more easily. According to the invention, this is achieved in that at least two printed contact tracks and/or two electrodes and/or at least one strain sensor are provided as means for sensing whether the package has been opened. This means that the use of conductive adhesives can be dispensed with. This lowers the costs of production of a corresponding package.

In an expedient development, at least two contact tracks and/or two electrodes which are arranged on different sides of a carrier material, such as a package blank or a film/foil, are provided as means for sensing whether a package has been opened. As a result, opening of the package can be sensed in a particularly simple manner by corresponding forming of the carrier material since the two contact tracks or electrodes interact with one another in the region of a tab of a folding box and therefore reliably identify removal of the tab from the inside of the package. A contact can then close by means of suitable contact points after the package blank is folded and in this way sensing of opening can be monitored.

In an expedient development, the means for sensing whether a package has been opened and/or the battery and/or the display and/or at least one conductor track are/is printed on a carrier material. Therefore, particularly simple and cost-effective production can be achieved, this additionally making use of similar technologies for packaging production such as conventional printing. As a result, handling of the carrier material or blank can be retained.

In an expedient development, when it is sensed that a package has been opened, at least one pulse is generated, the electronics system evaluates said pulse for sensing whether the package has been opened, and/or a capacitor is charged by means of said pulse. As a result, merely changes in a state can be monitored in a particularly simple manner.

In an expedient development, the means for sensing whether a package has been opened are fitted on the inside of the package. Therefore, these means, together with at least the associated electronics system and battery, are not visible to the consumer and, respectively, therefore do not need to be additionally masked either. This further simplifies the production process. This arrangement on the inside should preferably be achieved together with the strain sensor which, despite an internal arrangement, reliably detects sensing of an extension which is caused by an opening process.

In an expedient development, the electrode is designed in the form of a comb structure. The other electrode also has this form and is arranged such that the fingers of the electrodes interengage. Therefore, a change in capacitance can be detected in a particularly reliable manner.

In an expedient development, a timer and/or the display and/or detection of an item of information from a sensor and/or a radio module are/is activated depending on opening of the package being sensed. Therefore, for example, the time of opening could be detected and communicated by means of display or radio. Starting of a timer is also particularly advantageous since it is possible to monitor the shelf life in this simple way. Wastage of food products, particularly in the food industry, can be considerably reduced in this way.

In an expedient development, at least one operator control element is provided for influencing the display and/or at least one radio module and/or at least one timer and/or at least one sensor for determining a temperature and/or a pressure, in particular atmospheric pressure, and/or acceleration and/or vibration and/or a gas of a packaged food product. A consumer or purchaser or any other person can call up information at the desired time and receive said information in a suitable way in a particularly simple manner.

In comparison, the method according to the invention for producing a device has the advantage that simple production with technologies which are conventional for producing packaging is possible. In particular, the supply lines or the like can be retained and can be integrated into the production process in a particularly simple manner owing to similar technology.

In an expedient development, a timer is provided. Said timer is preferably activated depending on opening of the package being sensed. When the timer times out, the electronics system provides the consumer with a specific item of information, such as the expiration of the shelf life or the imminent end of the shelf life or the like for example. The display is particularly preferably correspondingly actuated for this purpose.

In an expedient development, at least one item of information, in particular relating to a product which is contained in the package, is sent by a radio module when the timer times out. The user can call up this information on any desired device, such as a smartphone, computer or the like, and is reliably informed in a particularly simple manner.

In an expedient development, a plurality of timers (multi-timer) are provided, it being possible for different information to be shown on the display and/or sent by means of the radio module when said plurality of timers time out. Therefore, the imminent expiration of the product can be indicated at staggered times.

In an expedient development, at least one operator control element is provided. As a result, the package can provide desired information in a user-friendly manner.

In an expedient development, it is provided that the operator control element is connected to the electronics system for the purpose of identifying one or more operations of the operator control element. The electronics system which is provided for actuating the display in any case is now also intended to evaluate the operator control element, and therefore the expenditure for the entire arrangement is not significantly increased.

In an expedient development, it is provided that the operator control element is connected to the electronics system for the purpose of identifying a duration of one or more operations of the operator control element. As a result, different operator control instructions can be realized using just one operator control element, without having to use further hardware.

In an expedient development, it is provided that different data sets and/or instructions are stored in the electronics system depending on the respective operation or the duration of the respective operation. Therefore, different information can be displayed and a choice can be made as to whether data should be transmitted on the display or by means of radio. Further functions, such as starting a timer, reading sensor data or the like, can also be performed in a particularly flexible manner.

In an expedient development, it is provided that different actuation operations for the display and/or the radio module and/or the electronics system and/or the timer and/or the sensor are provided in the electronics system depending on the respective operation of the operator control element or the duration of the respective operation of the operator control element. This increases the ease of operation of the device.

In an expedient development, it is provided that, when the operator control element is operated, data which is determined by the sensor is displayed and/or output by means of the radio module. Therefore, precise information about the conditions in the area surrounding the package or the product can be collected as required.

In an expedient development, it is provided that at least one further operator control element is provided. As a result, a large number of different instructions can be input in a rapid manner.

In an expedient development, it is provided that the electronics system comprises at least one switching means, preferably a transistor, which actuates the display depending on operation of the operator control element. Therefore, a display can be controlled using a simple circuit.

In an expedient development, a sensor is provided for the purpose of determining, preferably, a temperature and/or a pressure, in particular atmospheric pressure, and/or a force and/or acceleration and/or vibration and/or a gas. As a result, additional information relating to the package and/or the packaged product can be individually generated and provided. Therefore, data of interest can be reliably detected during the course of different processing steps of production, packaging, transportation, provision in shops until sale of the respective package or product etc. This is advantageous for the consumer from quality control to displaying relevant information.

In an expedient development, the electronics system actuates the sensor for detecting data depending on operation of the operator control element and/or an instruction which is transmitted by the radio module. Therefore, the data can be checked in a targeted manner at desired times, such as when packages are placed in sales spaces or during an incoming inspection. A check can also be made automatically when the corresponding instructions are sent to the packages within range by means of radio.

In an expedient development, it is provided that the electronics system compares the data which is determined by the sensor with a limit value. The electronics system particularly expediently generates at least one associated message when the limit value is exceeded or undershot. Therefore, the package is equipped with corresponding evaluation intelligence, so that corresponding messages can be directly displayed without evaluation in a central computer. To this end, the electronics system particularly expediently outputs the data from the sensor and/or the associated message by means of the display and/or the radio module when the limit value is exceeded or undershot.

In a particularly expedient development, it is provided that the electronics system outputs the data from the sensor and/or the associated message by means of the display and/or the radio module when the package is opened and/or when the operator control element is operated and/or when the timer times out and/or an instruction is transmitted by the radio module. The user can then acquire the current data at the desired time, for example during a final inspection, during delivery of the products which are packaged by the package or before the package is placed in a shop or when the package is opened.

In an expedient development, it is provided that the electronics system changes timing out of the timer depending on the data which is determined by the sensor. Therefore, special monitoring for individual products and/or packages is possible. By way of example, a shorter shelf life of the packaged product is to be expected at relatively high temperatures, and therefore the timer is started with a shorter time period. Or, if the sensor already detects an elevated or critical ethylene content, a shorter time is set on the timer than in the case of non-critical values.

In an expedient development, it is provided that the electronics system stores a profile of the data which is determined by the sensor. Therefore, the product and/or package quality can be tracked over a long period. This could be used as evidence for any product liability cases which may occur.

Further expedient developments can be gathered from the claims and the description.

### BRIEF DESCRIPTION OF THE DRAWINGS

Exemplary embodiments of the device according to the invention for sensing whether a package has been opened are illustrated in the drawing and will be described in greater detail in the text which follows.

In the drawing:

FIG. 1 shows a perspective view of the package with sensing of opening using contact tracks,

FIG. 2 shows an alternative refinement of the package with sensing of opening using electrodes,

FIG. 3 shows a further alternative refinement of the package with sensing of opening using a strain sensor,

FIG. 4 shows a further alternative exemplary embodiment using corresponding sensors,

FIG. 5 shows a package with an integrated timing function,

FIG. 6 shows a package with an integrated operator control element,

FIGS. 7 to 11 show different production steps of a package with sensing of opening,

FIG. 12 shows a circuit with the operator control element not operated, and

FIG. 13 shows the circuit according to FIG. 12 with the operator control element operated.

### DETAILED DESCRIPTION

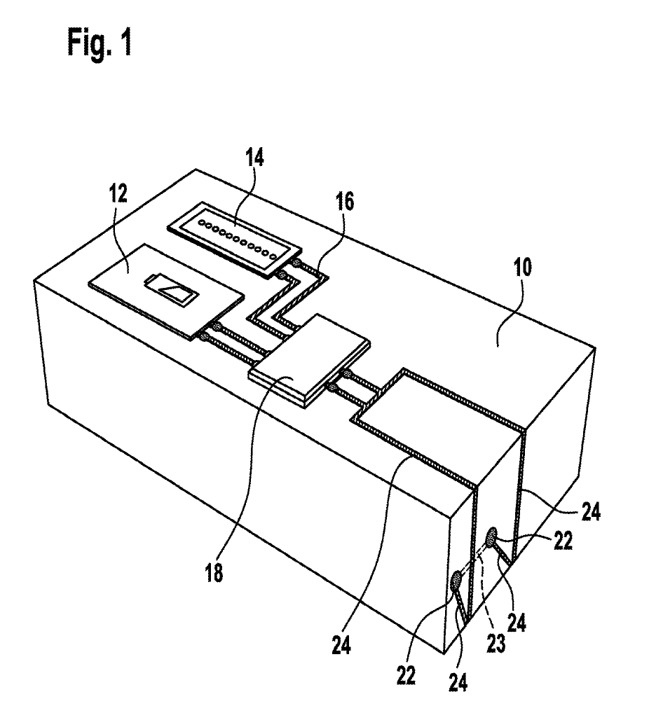

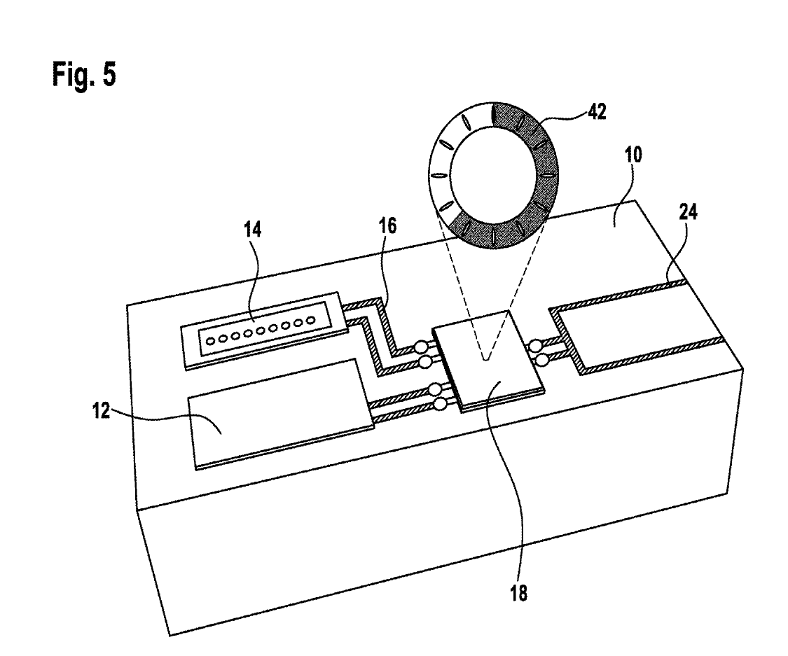

A package 10 is shown in the exemplary embodiment according to FIG. 1. A battery 12, a display 14 and contact tracks 16 are arranged on the top side of the package 10. The contact tracks 16 connect the battery 12 and the display 14 to an electronics system 18. Further contact tracks 24, specifically two contact tracks 24, which run in the direction of the opening tab of the package 10, preferably a folding box, are arranged on that side of the electronics system 18 which is situated opposite the battery 12. The two contact tracks 24 each run to a contact point 22. A further contact track 23 which runs parallel to the opening tab is located on the inside of the package 10. The electrical circuit is closed in the closed state of the package 10. If the package 10 is now opened on that side which is provided with the contact tracks 23, 24, the electrical circuit is interrupted. The electronics system 18 identifies this and concludes that the package 10 has been opened. Therefore, the contact tracks 23, 24 serve as means for sensing whether the package 10 has been opened. In this case, the two contact tracks 23, 24 are connected by means of the contact points 22 in the closed state of the package 10 such that an electrical circuit is closed. The first contact tracks 24 are located together with the electronics system 18, the battery 12 and the display 14 on the top side or outside of the package 10 or on one side of a package blank 11. The further contact tracks 23 is located on the opposite side of the package blank 11 or on the inside of the package 10. The package blank 11 is folded such that the first contact tracks 24 protrude over the end-side tab into the interior of the package 10 and make contact with the further contact track 23, which is situated on the inside, by means of the respective contact points 22. Further details can be gathered from FIGS. 6 to 10.

As an alternative, the means for sensing whether a package has been opened can also be realized in a capacitive manner or else in an inductive manner. It is important that opening of the package results in a change in an electrical variable, which change can be sensed and detected by the electronics system 18.

The battery 12 may preferably be a printed battery. Similarly, the display 14 should be provided as a printed display option. The conductor tracks 16 and the contact tracks 23, 24, and also the contact points 22, can likewise be provided in printed form. The electronics system 18 is a conventional circuit in the form of a chip which is fitted onto the package 10. As an alternative, the electronics system 18 could also be a printed circuit.

If the opening tab of the package 10 is now opened, current no longer flows across the contact points 22 to the contact track 24, and therefore the electronics system 18 identifies opening. A corresponding item of information relating to the opened package 10 can be signaled to the consumer, for example by means of the display 14.

In an alternative refinement, the contact tracks 23, 24 can also be designed such that they sense further regions of the package 10 in order to reliably identify opening at other points too. In an alternative refinement, the contact track 24 could also be designed as a sensor film/foil. As an alternative, the means for sensing whether a package has been opened can also be realized in a capacitive or inductive manner. It is important that opening of the package results in a change in an electrical variable, which change can be sensed and detected by the electronics system 18.

When sensing opening of a package 10, at least one pulse could preferably be generated, the electronics system 18 evaluating said pulse for sensing whether the package has been opened, and/or a capacitor being charged by means of said pulse. The electronics system 18 detects a corresponding change in capacitance and in this way concludes that the package 10 has been opened.

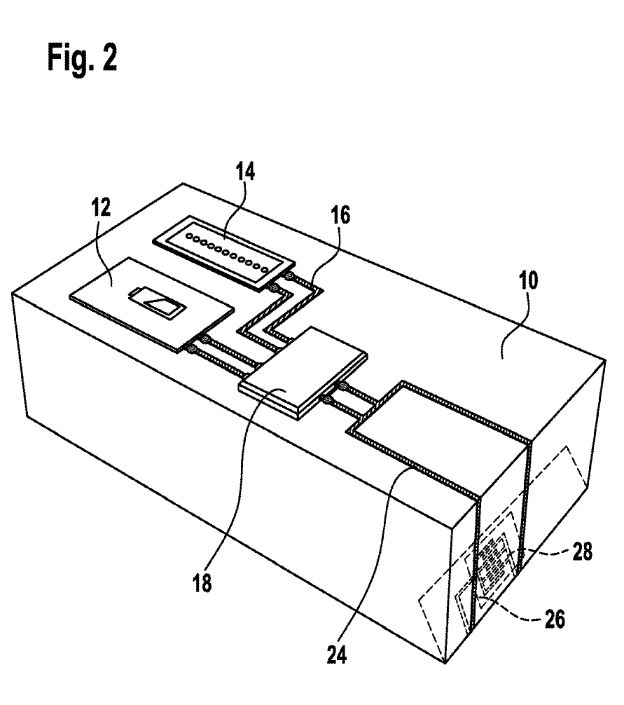

In an alternative exemplary embodiment according to FIG. 2, the opening process of the package 10 is monitored in a capacitive manner. A first electrode 26 and a second electrode 28 are provided for this purpose. One electrode 26 sits on the inside of the package, and the other electrode 28 sits on the inside of the opening tab. First and/or second electrodes 26, 28 can be designed, for example, in the form of a comb structure. The respective fingers of the comb structures interengage. A change in position of the electrodes 26, 28 causes a change in capacitance, which change can be sensed by the electronics system 18. Therefore, the electrodes 26, 28 likewise serve as means for sensing whether the package 10 has been opened.

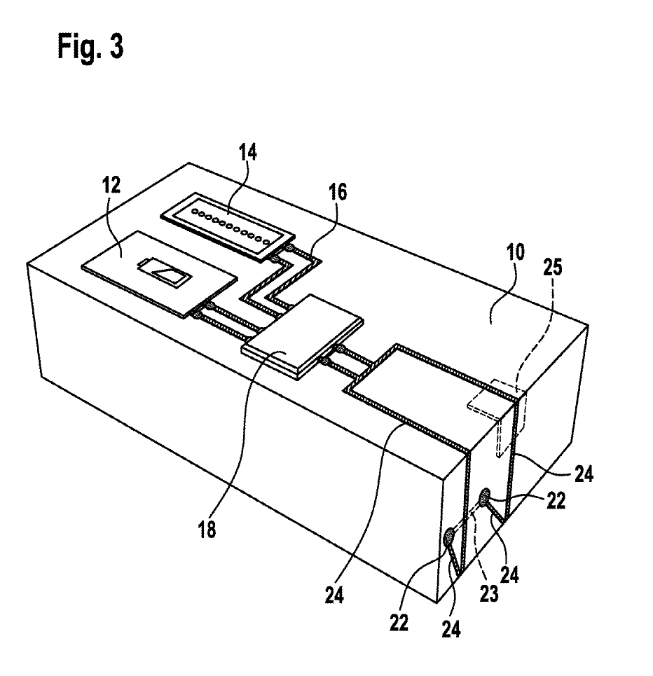

In an alternative refinement according to FIG. 3, a strain sensor 25 is arranged in the region of the contact tracks 24, preferably in the region of the tab around an edge of the package 10. Said sensor senses when extension of the tab is achieved by an opening process. The corresponding change in signal from the strain sensor 25 is detected by the electronics system 18 and possibly passed to the display 14. In this case, both the strain sensor 25 and also further components (conductor tracks 16, contact tracks 24, electronics system 18 and battery 12) can be arranged on the inside of the package 10. Therefore, this is advantageous since special measures are no longer required to cover said components in some other way. In the simplest case, the display 14 is likewise arranged on the inside and is also visible from the outside, for example by means of a transparent film. As an alternative, contact is made with the display 14, which is seated on the outside of the package 10, through the package 10.

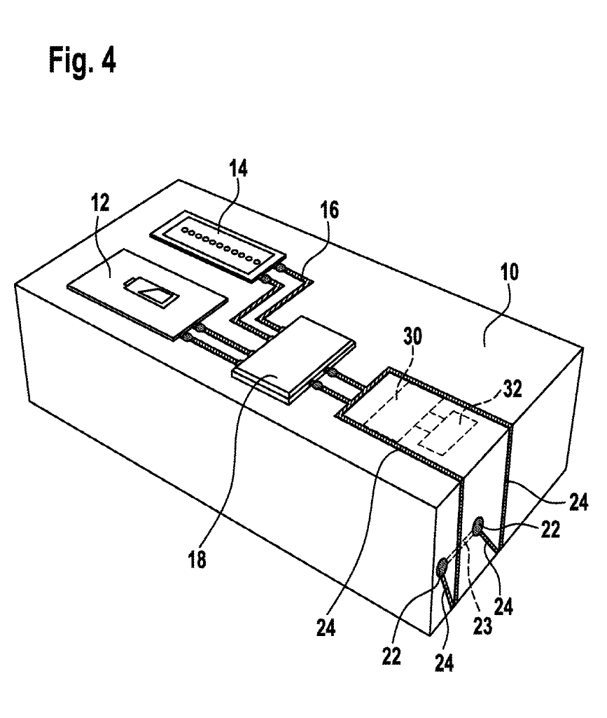

In an alternative refinement according to FIG. 4, further components, such as at least one sensor 30 and a radio module 32, are provided.

The sensor 30 could be, for example, a temperature sensor. Said temperature sensor detects the temperature of the package 10 in order to monitor, for example, the temperature in the interior of the package as to whether specific temperature profiles are being maintained. To this end, the detected temperature could be compared, for example, with a temperature profile which is stored in the memory of the electronics system 18. If specific limit values are exceeded, this could be communicated to the user on the display 14 and/or by means of the radio module 32. As an alternative, a pressure sensor could also be provided as sensor 30. In this case, the atmospheric pressure can be detected for example. Therefore, corresponding setpoint atmospheric pressure profiles can be monitored and processed further if necessary. This is of interest particularly in the case of packages 10 which are closed in an airtight manner, in order to acquire information about whether the package 10 has been opened in the event of deviations from a setpoint pressure. In a further alternative exemplary embodiment, the sensor 30 is in the form of a vibration sensor. In this case, it is possible to monitor, for example, whether the package 10 has been unintentionally dropped and whether the contents of the package may have been damaged. In an expedient development, a gas sensor is provided as sensor 30. A gas sensor of this kind is able to detect, for example, the ethylene content, for example for identifying the degree of maturity of fruit. A corresponding evaluation is performed in the electronics system 18, so that a corresponding message appears on the display 14 when a specific ethylene content is exceeded. Therefore, the sensors 30 can sometimes be used as means for sensing whether a package 10 has been opened. The sensors 30 used can be printed sensors or sensors which are manufactured in a conventional manner.

The sensor 30 can particularly preferably be arranged on the package 10 together with further components, such as at least one radio module 32 and/or at least one timer 42 and/or at least one operator control element 50, for example, as required. Therefore, an advantageous combination can be achieved, for example, when the electronics system 18 actuates the sensor 30 for detecting data depending on operation of the operator control element 50 and/or an instruction which is transmitted by the radio module 32. The user can then acquire the current data at the desired time, for example during final inspection, during delivery of the products which are packaged by the package 10 or before the package is placed in a shop. In addition, inspection and/or sensing could be automated by the sensor or the sensors 32 being activated by means of the radio module 32 and associated messages, such as faulty product, package 10 damaged, temperature profile critical, permissible pressure exceeded, ethylene content critical or the like, being possibly displayed and/or reported by means of the radio module 32 after the data is preliminarily processed by the electronics system 18. In addition, only critical states could also be reported. To this end, the electronics system 18 compares the data which is determined by the sensor 30 with a limit value. At least one associated message, as illustrated by way of example above, is generated when the limit value is exceeded or undershot. The data from the sensor 30 and/or the associated message are/is output by means of the display 14 and/or the radio module 32 when the limit value is exceeded or undershot. As an alternative or in addition, it could also be provided that the electronics system 18 outputs the data from the sensor 30 and/or the associated message by means of the display 14 and/or the radio module 32 when the package 10 is opened and/or when the operator control element 50 is operated and/or when the timer 42 times out and/or an instruction is transmitted by the radio module 32. Specifically when a timer 42 times out and/or when opening of the package 10 is sensed, a message can be automatically generated and displayed to the user if desired. As an alternative or in addition, it could also be provided that the electronics system 18 changes timing out of the timer 42 depending on the data which is determined by the sensor 30. By way of example, a shorter shelf life of the packaged product is to be expected at relatively high temperatures, and therefore the timer 42 is started with a shorter time period. Or, if the sensor 30 already detects an elevated or critical ethylene content, a shorter time is set on the timer 42 than in the case of non-critical values. Therefore, special monitoring for individual products and/or packages is possible. As an alternative or in addition, the electronics system 18 stores a profile of the data which is determined by the sensor 30. Therefore, the product and/or package quality can be tracked over a long period. This could be used as evidence for any product liability cases which may occur. Furthermore, only one sensor 30 or else further sensors 30 could be provided.

The radio module 32 could be, for example, a transponder technology, such as RFID, WLAN, Bluetooth, NFC (near field communication). The radio module 32 sends corresponding data to an evaluation unit which is arranged remote from the package 10. Said data may be data which has been detected by the sensor 30 and possibly conditioned by the electronics system 18. Determination of opening of the package 10, the time of opening and/or timing out of a timer 42, as described below, could also be sent. The radio module 32 could also be realized in a printed or conventional manner.

In an alternative exemplary embodiment according to FIG. 5, a timer 42 is provided in the electronics system 18. The electronics system 18 detects opening of the package 10 and starts the timer 42. If a specific time interval is exceeded, a corresponding message, such as expiration of the packaged product for example, follows. As an alternative or in addition, the electronics system 18 stores a specific item of information, preferably relating to a product which is contained in the package 10, when the timer 42 times out.

As an alternative, a plurality of timers 42 could also be provided, it being possible for different information, in particular relating to a product which is contained in the package 10, to be shown on the display 14 and/or stored and/or sent by means of the radio module 32 when said timers time out.

In an alternative exemplary embodiment according to FIG. 6, at least one operator control element 50 is provided in addition to the battery 12, the display 14, the conductor tracks 16 and the electronics system 18. As an alternative, a plurality of operator control elements 50 could also be provided. The operator control element 50 is arranged on the outside of the package 10. A user can operate said operator control element. The electronics system 18 identifies operation, for example due to a change in electrical variables. A memory, in which the data which is to be shown on the display 14 is stored, is located in the electronics system 18. In this case, it would be feasible to activate the display 14, or to switch said display further with each further operation and to show different information on the display 14.

As an alternative, further components, which are described in the preceding exemplary embodiments, can also be provided. In particular, means 23, 24, 25, 26, 28 for sensing whether a package has been opened and/or the radio module 32 and/or one or more sensors 30 for determining a temperature and/or a pressure or atmospheric pressure and/or acceleration and/or vibration and/or a gas could be provided.

The electronics system 18 can particularly preferably also be equipped to identify the duration of one or more operations of the operator control element 50. Different data sets or else actuation operations are stored in the electronics system depending on the respective operation and/or the duration of the respective operation.

Therefore, the electronics system 18 actuates the display 14 and/or the radio module 32 and/or a memory and/or the timer 42 and/or the sensor 30 for detecting sensor data depending on operation of the operator control element 50. Therefore, it would be feasible, for example, for a different item of information relating to the product which is contained in the package 10 to be displayed when the operator control element 50 is operated, for example a different language, a different item of information such as shelf life, contents or else data which is of interest in respect of logistics, such as delivery, storage, origin, transportation, security code or the like. As an alternative or in addition, information of this kind could also be passed on by means of the radio module 32.

A timer 42 could also be started, for example in order to display an item of information for a limited time, and/or a different item of information could be automatically shown on the display after the timer 42 times out depending on operation of the operator control element 50. Said information could be, for example, price information which is changed after a specific time period expires, for example before the shelf life expires, and therefore the product automatically becomes a product on special offer.

As an alternative, the electronics system 18 could also check current data from the sensor 30 and show said data on the display 14 and/or output said data by means of the radio module 32 and/or store said data in the electronics system 18 when the operator control element 50 is operated. In this case, the sensor data could be detected and also processed further in the electronics system 18 when said sensor data is compared with stored limit values and is output, be it by means of the display 14 and/or the radio module 32, depending on corresponding information being exceeded.

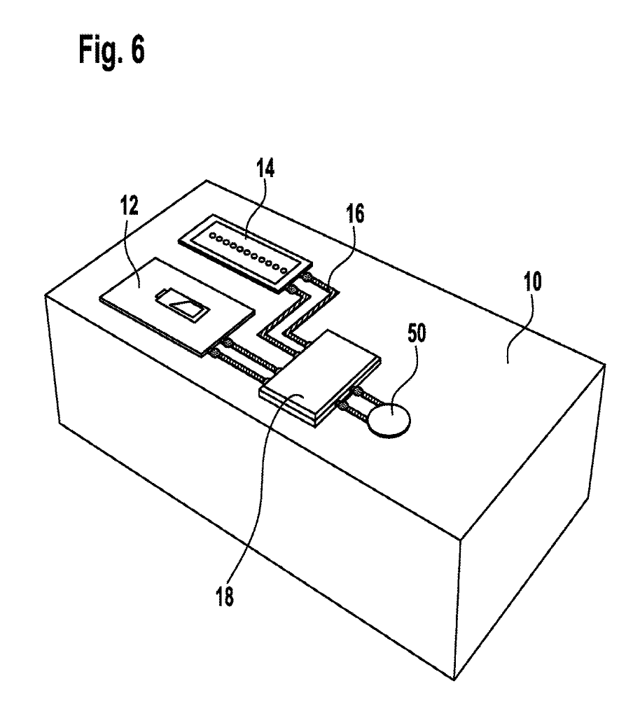

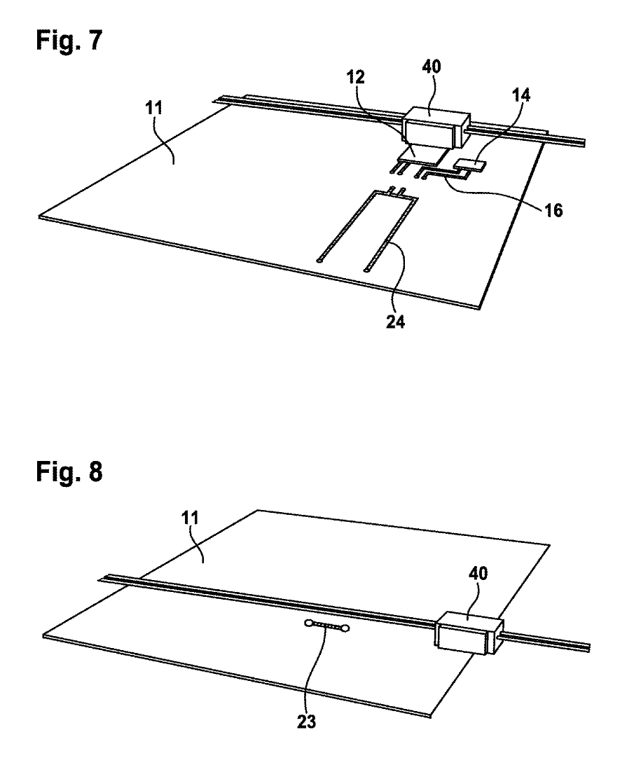

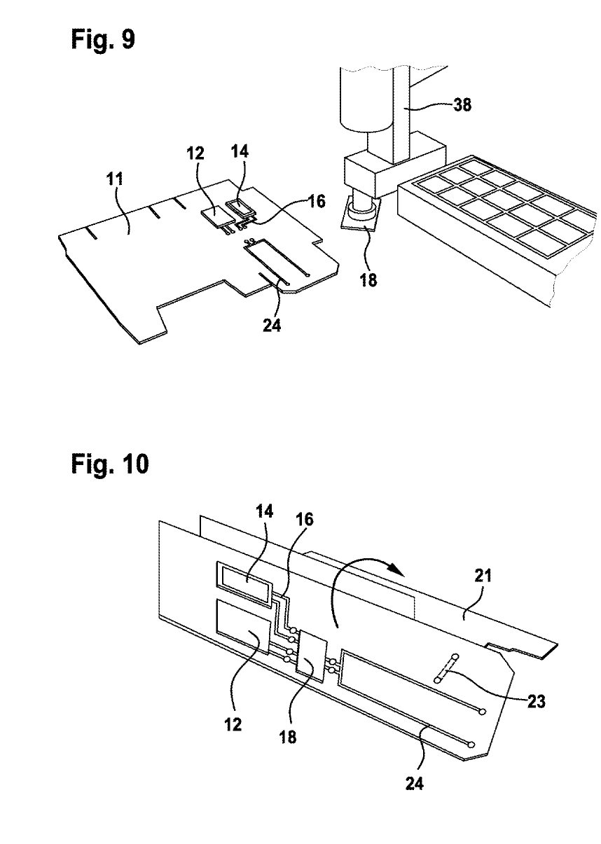

FIGS. 7 to 10 show different steps in the production of a package with the components of the exemplary embodiment according to FIG. 1. These production steps can also be transferred to the other exemplary embodiments in principle. The package blank 11 for the package 10 is in the flat state. A pushbutton 40 brings together the conductor tracks 16, the display 14 and the battery 12 and the contact tracks 24 (not shown) in succession (on a row by row basis) according to FIG. 7. The package blank 21 is then turned over onto the other side. The contact track 23 is printed on said other side (FIG. 8). The package blank 11 is then punched out in order to be subsequently folded to form a folding box. The electronics system 18 is fitted in a further method step (FIG. 9). A corresponding handling device 38, such as a robot for example, which positions and fastens the electronics unit 18 at the corresponding point of the blank 11 is provided for this purpose. The punched-out blank 11 is folded to form a folding box, as indicated by the arrow. In the process, the contact points 22 of the contact tracks 24 come into electrically conductive contact with those of the further contact track 23.

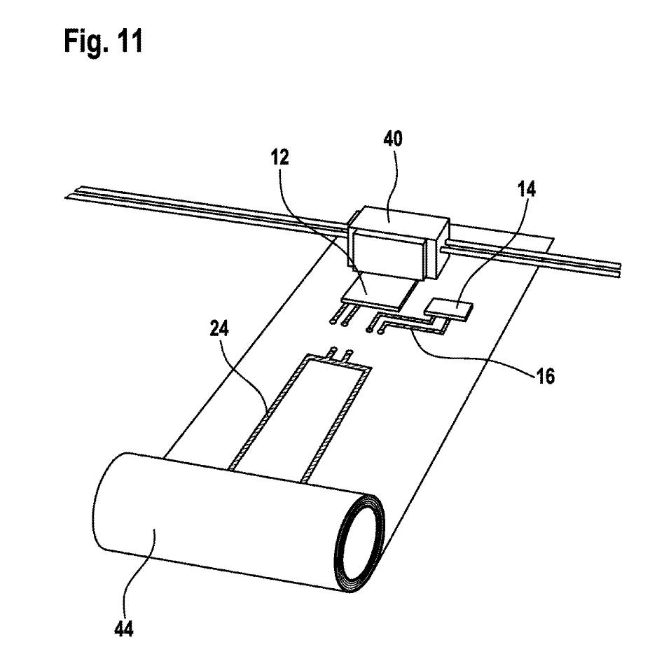

In an alternative manufacturing variant, the components battery 12, display 14, conductor tracks 16 are printed onto a film/foil 44 (FIG. 11). The electronics system 18 is once again applied and fastened on the film/foil 44. The film/foil 44 which has been correspondingly prepared for this is connected to the package blank 11. In a final step, those components which are not intended to be visible to the consumer, such as the battery 12, the conductor tracks 16, the electronics system 18 and the contact tracks 24 for example, are printed over. Only the display 14 remains visible.

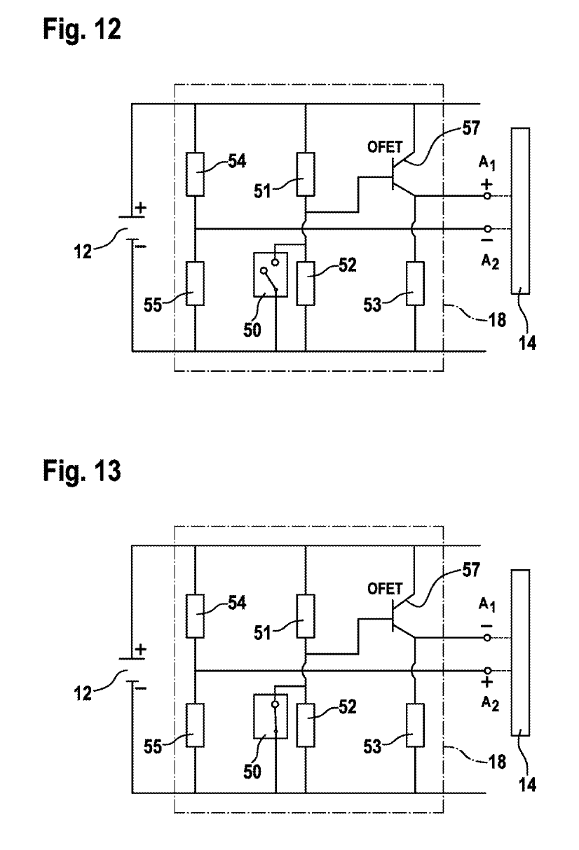

An elegant solution for a switching process for the display 14 is performed using a pushbutton as an example of an operator control element 50. Five resistors 51-55 and a switching means, such as an OFET for example, are provided for a corresponding circuit. In the circuit according to FIGS. 12 and 13, the display 14 can be connected to a positive pole of the battery 12 by means of a switching means 57. The other output of the switching means 57 is connected to a negative pole of the battery 12 by means of a third resistor 53. The negative connection of the display 14 is connected to the battery 12 by means of a voltage divider which is formed from a fourth resistor 54 and a fifth resistor 55. A first resistor 51 is connected to the positive pole of the battery 12, and the other connection of said first resistor is connected both to a control input of the switching means 57 and also to a connection of a second resistor 52. Another connection of the second resistor 52 is connected to the negative potential of the battery 12. The operator control element 50 is connected in parallel to the second resistor 52.

The display change can be realized with the circuit diagram according to FIGS. 12 and 13. If the operator control element 50, such as a film/foil pushbutton, is not operated, the control current of the switching means 57 flows via the first resistor 51 to the switching means 57, a transistor in the exemplary embodiment. The switching means 57 switches and allows the electric current to flow across its source-drain connection. A positive supply current is applied to one connection A1 of the display 12. If the operator control element 50, the film/foil pushbutton, is then operated, the switching means 57 is opened, that is to say the transistor turns off, and the control current flows back to the battery directly via the first resistor 51 and the operator control element 50. Therefore, a negative supply current is applied to the connection A1 of the display 14. This concept can be used for all feasible package types which have enough space for a battery 12 and a display 14.

The package 10 could be, for example, folding boxes, tubular bags, bottles, thermoformed plastic containers (cups, trays, blister packs) or other containers.

1. A device for sensing whether a package has been opened, comprising at least one package (10), at least one electronics system (18), at least one battery (12) which supplies energy to the electronics system (18), at least one display (14) configured to be actuated by the electronics system (18), and at least one means (23, 24, 25, 26, 28) for sensing whether the package (10) has been opened, wherein the electronics system (18), the battery (12), the display (14) and the means (23, 24, 25, 26, 28) for sensing whether a package has been opened are arranged on the package (10), characterized in that at least two printed contact tracks (23, 24) and/or two electrodes (26, 28) and/or at least one strain sensor (25) are provided as means for sensing whether the package (10) has been opened.

2. The device as claimed in claim 1, characterized in that at least two contact tracks (23, 24) and/or two electrodes (26, 28) which are arranged on different sides of a package blank (11), which forms the package (10), are provided as means for sensing whether a package has been opened.

3. The device as claimed in claim 1, characterized in that the means (23, 24, 25, 26, 28) for sensing whether a package has been opened and/or the battery (12) and/or the display (14) and/or at least one conductor track (16) are/is printed on a carrier material such as a package blank (11) and/or a film/foil (44) as a constituent part of the package (10).

4. The device as claimed in claim 1, characterized in that, when it is sensed that a package (10) has been opened, at least one pulse is generated, the electronics system (18) evaluates said pulse for sensing whether the package has been opened, and/or a capacitor is charged by means of said pulse.

5. The device as claimed in claim 1, characterized in that the means (23, 24, 25, 26, 28) for sensing whether a package has been opened and/or the electronics system (18) are fitted on the inside of the package (10).

6. The device as claimed in claim 1, characterized in that the electrode (26, 28) is in the form of a comb structure.

7. The device as claimed in claim 1, characterized in that a timer (42) and/or the display (14) and/or detection of an item of information from a sensor (30) and/or a radio module (32) are/is activated depending on opening of the package (10) being sensed.

8. The device as claimed in claim 1, characterized in that at least one operator control element (50) is provided for influencing the display (14) and/or at least one radio module (32) and/or at least one timer (42) and/or at least one sensor (30) for determining a temperature and/or a pressure and/or acceleration and/or vibration and/or a gas.

9. The device as claimed in claim 1, characterized in that the means (23, 24, 25, 26, 28) for sensing whether a package has been opened is arranged in an opening region of the package (10).

10. A method for producing a device as claimed in claim 1, characterized by the following steps:
printing a carrier material with at least one conductor track (16) and/or at least one energy store and/or at least one display (14), and
fitting at least one means (23, 24, 25, 26) for sensing whether a package has been opened onto the carrier material (11, 44), wherein said means includes at least two contact tracks (23, 24) and/or two electrodes (26, 28) and/or at least one strain sensor (25).

11. The method as claimed in claim 10, characterized in that at least one electronics system (18) and/or a sensor (30) and/or a radio module (24) are fitted onto the carrier material (11, 44).

12. The method as claimed in claim 10, characterized in that at least one contact track (24) and/or an electrode (26) are/is printed on one side of the carrier material (11, 44), and at least one further contact track (23) and/or further electrodes (28) are/is printed on the opposite side of the carrier material (11, 44).

13. The method as claimed in claim 10, characterized in that the carrier material (11, 44) is formed such that the at least one conductor track (24) and/or electrode (26) interacts with at least one further contact track (23) and/or electrode (28) for the purpose of sensing whether a package has been opened.

14. The method as claimed in claim 10, characterized in that the carrier material (11, 44) is formed at least as part of a package material for forming a package (10).

15. The method as claimed in claim 10, characterized in that the carrier material (44) is connected to a package material.

16. The device as claimed in claim 1, characterized in that at least one operator control element (50) is provided for influencing the display (14) and/or at least one radio module (32) and/or at least one timer (42) and/or at least one sensor (30) for determining a temperature and/or an atmospheric pressure and/or acceleration and/or vibration and/or a gas.

17. The device as claimed in claim 1, characterized in that the means (23, 24, 25, 26, 28) for sensing whether a package has been opened is arranged in a region of an opening tab of the package (10).

18. The method as claimed in claim 10, characterized in that at least one electronics system (18) and/or a sensor (30) and/or a radio module (24) are fitted onto the carrier material (11, 44) by a handling unit (38).

19. The method as claimed in claim 10, characterized in that the carrier material (44) is a film/foil and is connected to a package material.

20. A method for producing a device as claimed in claim 1, characterized by the following steps:
printing a carrier material, wherein the carrier material is a package blank (11) and/or a film/foil (44), with at least one conductor track (16) and/or at least one battery (12) and/or at least one display (14), and
fitting at least one means (23, 24, 25, 26) for sensing whether a package has been opened onto the carrier material (11, 44), wherein said means includes at least two contact tracks (23, 24) and/or two electrodes (26, 28) and/or at least one strain sensor (25).
